(19) United States
(12) Patent Application Publication
(10) Pub. No.: US 2010/0095998 A1
(43) Pub. Date: Apr. 22, 2010

(54) LOW RESISTANCE TUNNEL JUNCTIONS FOR HIGH EFFICIENCY TANDEN SOLAR CELLS

(75) Inventors: Wladyslaw Walukiewicz, Kensington, CA (US); Joel W. Ager, III, Berkeley, CA (US); Kin Man Yu, Lafayette, CA (US)

Correspondence Address: FULBRIGHT & JAWORSKI, LLP, 666 FIFTH AVE, NEW YORK, NY, 10103-3198, US

(73) Assignee: The Regents of the University of California, Oakland, CA (US)

(21) Appl. No.: 12/528,394

(22) PCT Filed: Apr. 9, 2008
(86) PCT No.: PCT/US08/04572

§ 371 Date: Jan. 5, 2010

Related U.S. Application Data
(60) Provisional application No. 60/910,734, filed on Apr. 9, 2007.

(51) Int. Cl. H01L 31/042; H01L 31/0304

(52) U.S. Cl. 136/244; 257/E31.022

(57) ABSTRACT

A semiconductor structure comprises a first photovoltaic cell comprising a first material, and a second photovoltaic cell comprising a second material and connected in series to the first photovoltaic cell. The conduction band edge of the first material adjacent the second material is at most 0.1 eV higher than a valence band edge of the second material adjacent the material. Preferably, the first material of the first photovoltaic cell comprises ln].χAlχN or lnt_yGayN and the second material of the second photovoltaic cell comprises silicon or germanium. Alternatively, the first material of the first photovoltaic cell comprises InAs or InAsSb and the second material of the second photovoltaic cell comprises GaSb or GaAsSb.

### STATEMENT OF GOVERNMENTAL SUPPORT

The invention described and claimed herein was made in part utilizing funds supplied by the U.S. Department of Energy under Contract No. DE-AC02-05CH11231. The government has certain rights in this invention.

### BACKGROUND OF THE INVENTION

This invention relates to tandem photovoltaic or solar cells, more particularly to low resistance tunnel junctions for high efficiency tandem solar or photovoltaic cells and method of fabricating same.

As used herein, the term “photovoltaic cell” includes any semiconductor p/n junction that can convert photons to electricity. This includes, but is not limited to, commonly known photovoltaic cells that convert visible light into electricity, and thermo-photovoltaic cells that convert long-wavelength or thermal photons to electricity.

These photovoltaic cells are usually characterized by solid crystalline structures that have energy band gaps between their valence electron bands and their conduction electron bands. When light is absorbed by the material, electrons that occupy low-energy states become excited to cross the band gap to higher energy states. For example, when electrons in the valence band of a semiconductor absorb sufficient energy from photons of the solar radiation, they can jump the band gap to the higher energy conduction band. Electrons which are excited to higher energy states leave behind unoccupied low-energy positions or holes. Such holes can shift from atom to atom in the crystal lattice and thereby act as charge carriers, as do free electrons in the conduction band, and contribute to the crystal's conductivity. Most of the photons absorbed in the semiconductor give rise to such electron-hole pairs which generate the photocurrent and, in turn, the photo-voltage exhibited by the solar cell. The semiconductor is doped with a dissimilar material to produce a space charge layer which separates the holes and electrons for use as charge carriers. Once separated, these collected hole and electron charge carriers produce a space charge that results in a voltage across the junction, which is the photo-voltage. If these hole and charge carriers are allowed to flow through an external load, they constitute a photocurrent.

There is a fixed quantum of potential energy difference across the band gap in the semiconductor. For an electron in the lower energy valence band to be excited to jump the band gap to the higher energy conduction band, it has to absorb a sufficient quantum of energy, usually from an absorbed photon, with a value at least equal to the potential energy difference across the band gap. The semiconductor is transparent to radiation, with photon energies less than the band gap. If the electron absorbs more than the threshold quantum of energy, e.g., from a higher energy photon, it can jump the band gap. The excess of such absorbed energy over the threshold quantum required for the electron to jump the band gap results in an electron that is higher in energy than most of the other electrons in the conduction band. The excess energy is eventually lost in the form of heat. The net result is that the effective photo-voltage of a single band gap semiconductor is limited by the band gap. Thus, in a single semiconductor solar cell, to capture as many photons as possible from the spectrum of solar radiation, the semiconductor must have a small band gap so that even photons having lower energies can excite electrons to jump the band gap. This has limitations because the use of a small band gap material results in a low photo-voltage and lower power output for the device. Additionally, the photons from higher energy radiation produce excess energy which is lost as heat.

Whereas, if the semiconductor is designed with a larger band gap to increase the photo-voltage and reduce energy loss caused by thermalization of hot carriers, then the photons with lower energies will not be absorbed. Consequently, it is necessary to balance these considerations and optimize band gap in designing the single-junction solar cells, and try to design a semiconductor with an optimum band gap. Much work has been done in recent years to solve this problem by fabricating tandem or multi-junction (cascade) solar cell structures in which a top cell has a larger band gap and absorbs the higher energy photons, while the lower energy photons pass through the top cell into lower or bottom cells that have smaller band gaps to absorb lower energy radiation. The band gaps are ordered from highest to lowest, top to bottom, to achieve an optical cascading effect. In principle, an arbitrary number of sub-cells can be stacked in such a manner; however, the practical limit is usually considered to be two or three. Multi-junction solar cells are capable of achieving higher conversion efficiencies since each sub-cell converts solar energy to electrical energy over a small photon wavelength band, over which it converts energy efficiently. Techniques for making such tandem cells are described in U.S. Pat. No. 5,019,177, which is incorporated herein by reference in its entirety.

Efforts to improve the efficiency of photovoltaic devices have become more urgent with the rising cost of hydrocarbon based fuels. Most of the solar cells now on the market are made of silicon, but higher efficiency cells from other materials have been investigated in recent years. Particular interest has been focused on gallium arsenide and related alloys. As noted herein, significant increases in solar cell efficiency are possible from the use of tandem sub-cells of different materials, the different materials having different energy band gaps between their valence electron bands and their conduction bands. Lattice constants of compounds and alloys used to form photovoltaic cells are well-known. When such materials are combined in devices having sub-cells of the different materials, the lattice of the different materials should have the same lattice constants to within a small difference. This avoids the formation of defects in the crystal structures which can drastically lower the efficiency of the devices.

In any tandem cell device, electrical connections must be made between the sub-cells. Preferably, these inter-cell ohmic contacts should have minimal electrical resistance to cause very low loss of electrical power between cells. There are two methods known for making such inter-cell ohmic contacts, metal interconnects and tunnel junctions (or tunnel diodes). The metal interconnects can provide low electrical resistance, but they are difficult to fabricate, they result in complex processing and can cause substantial loss in the device efficiency. Therefore, tunnel junctions are generally preferred, because a monolithic integrated device can be produced having a plurality of sub-cells with tunnel junctions therebetween. But, the tunnel junctions must satisfy multiple requirements, such as low resistivity, high peak current density, low optical energy losses, and crystallographic compatibility through lattice-matching between top and bottom cells.

At present, tandem solar cells use tunnel junctions to ensure efficient current flow through the 2-4 photovoltaic cells that are connected in series. When the currents generated in each the sub-cell are matched, the cell functions most efficiently. For current to flow though the cell so that the sub-cell voltages add in series, a junction that allows electron-hole recombination between the sub-cells is useful.

In order to accommodate the band offsets in tandem cells currently, heavily doped tunnel junctions are used. The tunnel junction connects the top and middle cells of a standard three junction (3J) cell in order to efficiently annihilate holes, for example, from an InGaP top cell with electrons from an InGaAs middle cell. See, for example, tandem solar cells having indium phosphide sub-cell and indium gallium arsenide phosphide are described in U.S. Pat. Nos. 5,407,491 and 5,800,630, each of which is incorporated by reference in its entirety. Due to band misalignment between the valence band (VB) of the InGaP and the conduction band (CB) of the InGaAs, the tunnel junction is heavily doped to allow tunneling transport. In this case the junction is p++InGaP or p++AlGaAs and n++InGaAs or n++AlInP. This is undesirable because it adds additional process steps to the fabrication of the solar cells and increase the complexity of the design.

Therefore, it is desirable to provide low resistance tunnel junctions that does not add additional process steps to the fabrication of the solar cells and increase the complexity of the design of the solar cells.

### SUMMARY OF THE INVENTION

The present invention overcomes aforementioned shortcomings in prior art by providing low resistance tunnel junctions for high efficiency tandem solar cells.

It is therefore an object of the present invention to provide high efficiency tandem solar cells that does not require heavily doped tunnel junctions to ensure recombination at the cell junction regions.

It is another object of the present invention to provide and fabricate high efficiency indium nitride based tandem solar cells.

It is a further object of the present invention to provide an indium nitride based tandem solar cell as aforesaid that provides low or near-zero resistance tunnel junctions.

It is a still another object of the present invention to provide GaSb/InAsSb based tandem solar cell that provides low or near-zero resistance tunnel junctions.

In accordance with an embodiment of the present invention, a semiconductor structure comprises a first photovoltaic cell comprising a first material, and a second photovoltaic cell comprising a second material and connected in series to the first photovoltaic cell. The conduction band edge of the first material adjacent the second material is at most 0.1 eV higher than a valence band edge of the second material adjacent the material. Preferably, the first material of the first photovoltaic cell comprises In₁₋ₓAlₓN or In_{1-y}Ga_{y}N and the second material of the second photovoltaic cell comprises silicon or germanium.

Alternatively, the first material of the first photovoltaic cell comprises InAs and the second material of the second photovoltaic cell comprises GaSb. Preferably, the first material of said first photovoltaic cell comprises InAsSb and the second material of the second photovoltaic cell comprises GaAsSb.

In accordance with an embodiment of the present invention, a semiconductor structure comprises a p-type silicon layer, and an n-type semi-conducting nitride layer in contact with the p-type silicon layer. The n-type semi-conducting nitride layer has a conduction band edge at most 0.1 eV higher than a valence band edge of the p-type silicon layer. Preferably, the n-type semi-conducting nitride is selected from a group consisting of In₁₋ₓAlₓN and In_{1-y}Ga_{y}N, wherein x is preferably between 0.2 and 0.6 and y is preferably between 0.4 and 0.6. The p-type silicon layer is preferably (111) silicon or Si (111).

In accordance with an aspect of the present invention, the current-voltage characteristic of the semiconductor structure is symmetric. Preferably, a junction formed by the p-type silicon layer and the n-type semi-conducting nitride layer has a resistance substantially equal to a series resistance of the silicon and the nitride.

In accordance with an embodiment of the present invention, the semiconductor structure as aforesaid, further comprises a p-type semi-conducting nitride layer in contact with the n-type semi-conducting nitride layer and an n-type silicon layer in contact with the p-type silicon layer.

In accordance with an embodiment of the present invention, the n-type semi-conducting nitride layer is part of a first photovoltaic cell and the p-type silicon layer is part of a second photovoltaic cell in the semiconductor structure. The first photovoltaic cell and the second photovoltaic cell are connected together in series.

Various other objects, advantages and features of the present invention will become readily apparent from the ensuing detailed description, and the novel features will be particularly pointed out in the appended claims.

### BRIEF DESCRIPTION OF THE DRAWINGS

The following detailed description, given by way of example, and not intended to limit the present invention solely thereto, will best be understood in conjunction with the accompanying drawings in which:

FIG. 1 displays valence and conduction band positions of InAlN and InGaN alloys.

FIG. 2 is a band diagram of an InGaN/Si tandem cell incorporating a near zero-resistance tunnel junction in accordance with an exemplary embodiment of the present invention.

FIG. 3 shows a current-voltage curve for of a tunnel junction between n-InGaN and p-Si (111).

FIG. 4 is a tandem solar cell design incorporating the low resistance tunnel junction in accordance with an embodiment of the present invention.

FIG. 5 shows calculated efficiency values of a two junction (2J) InGaN/Si tandem solar cell as a function of the InGaN band gap in accordance with an exemplary embodiment of the present invention.

FIG. 6 shows the low resistance junction between p-type GaSb and n-type InAsSb in accordance with an exemplary embodiment of the present invention.

### DETAILED DESCRIPTION OF THE EMBODIMENTS

The band gap tuning range of group III-nitrides includes nearly the entire useful range of the solar spectrum with respect to energy conversion, making these materials attractive for use in photovoltaic cells. In order to increase efficiency and produce more power, it has become increasingly more common to design tandem photovoltaic cells made of thin films and connected electrically in series. But there have been difficulties associated with the series junctions.

As noted herein, the tandem solar cells use tunnel junctions to ensure efficient current flow through the multi-photovoltaic cells that are connected in series. When the currents generated in each the sub-cell are matched, the cell functions most efficiently. For current to flow though the cell so that the sub-cell voltages add in series, a junction that allows electron-hole recombination between the sub-cells is useful.

In order to accommodate the band offsets in tandem solar cells currently, heavily doped tunnel junctions are used. The tunnel junction connects the top and middle cells of a standard three junction (3J) cell in order to efficiently annihilate holes, for example, from an InGaP top cell with electrons from an InGaAs middle cell. Due to band misalignment between the valence band (VB) of the InGaP and the conduction band (CB) of the InGaAs, the tunnel junction is heavily doped to allow tunneling transport. In this case the junction is p++InGaP or p++AlGaAs and n++InGaAs or n++AlInP. This is undesirable because it adds additional process steps to the fabrication of the cell and increases the complexity of the design.

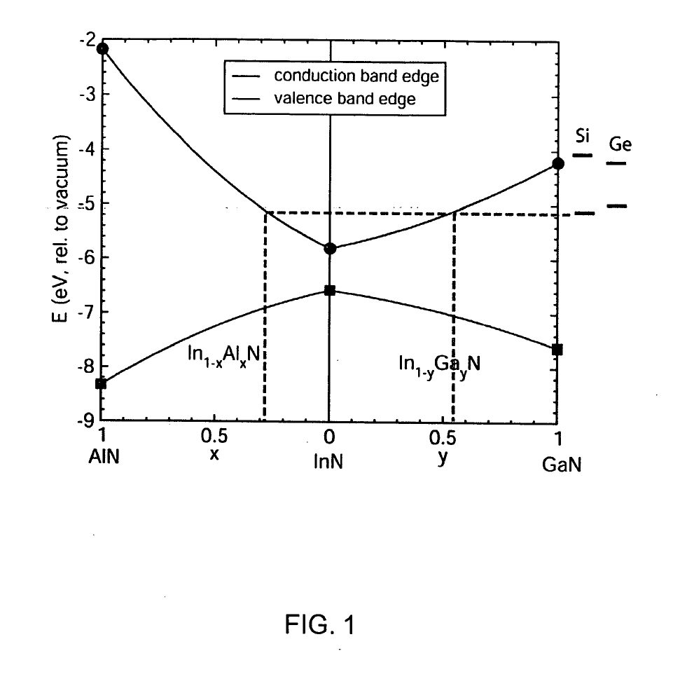

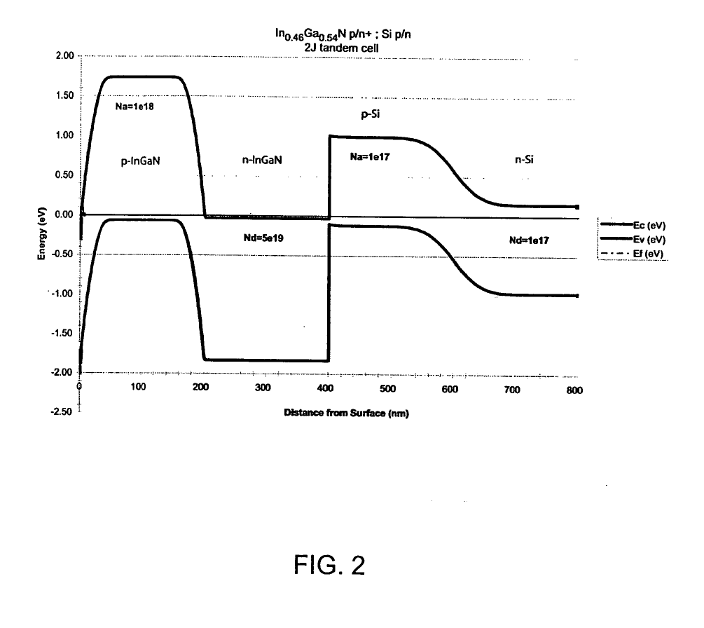

The absolute positions of the edges of the conduction band (CB) and valence band (VB) of indium aluminum nitride and indium gallium nitride alloys (In₁₋ₓAlₓN and In_{1-y}Ga_{y}N) were established through experimental work. See S. X. Li et al., “Fermi Level Stabilization Energy In Group III-nitrides,” Phys. Rev. B 71, 161201 (R) (2005), which is incorporated herein by reference in its entirety. FIG. 1 displays a graph wherein the energies of the CB and VB edges of In₁₋ₓAlₓN and In_{1-y}Ga_{y}N have been plotted as function of x and y. The positions of the VB edges and CB edges for silicon (Si) and germanium (Ge) are also shown in FIG. 1. The compositions that align the conduction band with the valence band of Si are indicated by dotted lines. The CB of In₁₋ₓAlₓN aligns with the VB of Si for an “x” value of approximately 0.3, corresponding to a composition of In_{0.7}Al_{0.3}N. The CB of In_{1-y}Ga_{y}N aligns with the VB of Si for a “y” value of approximately 0.5, corresponding to a composition of In_{0.5}Ga_{0.5}N. In accordance with an exemplary embodiment of the present invention, a junction can be formed between n-type type InAlN and p-Si or between n-type InGaN and p-Si that has near-perfect band alignment, thereby yielding a very low (close to zero or near zero) resistance tunnel junction. The calculations showing the near-perfect band alignment of the nitride-based tunnel junctions of the present invention are shown in FIG. 2. A similar near perfect or excellent band alignment exists for p-Ge at a higher Al (or Ga) content with x˜0.4 (or y˜0.6), corresponding to a composition of In_{0.6}Al_{0.4}N (or In_{0.4}Ga_{0.6}N). In general, band alignment is considered to be excellent when the conduction band edge is no more than about 0.1 eV higher than the valence band edge.

FIG. 2 shows a calculated band diagram for an In_{0.46}Ga_{0.54}N p/n+:Si p/n 2J tandem cell that has a near zero-resistance tunnel junction. The acceptor (Nₐ) and donor (N_{d}) concentrations for this calculation are 1×10¹⁸ cm⁻³ and 5×10¹⁹ cm⁻³, respectively. The InGaN and Si cells have p/n junctions and function as normal p/n junction (1J) solar cells, that is, under illumination, electrons in the nitride material flow into the cell away from the surface, and holes in the Si move toward the surface. The tunnel junction is located approximately 400 nm below the surface at the interface between n-InGaN and p-Si. Electrons from the n-InGaN and holes from the p-Si can recombine at the interface. Under this current matching condition, the voltages of the two cells can add in series. There is only a tiny amount of “band bending” at the interface due to the nearly perfect band alignment for the chosen InGaN composition. This leads to a very low resistance.

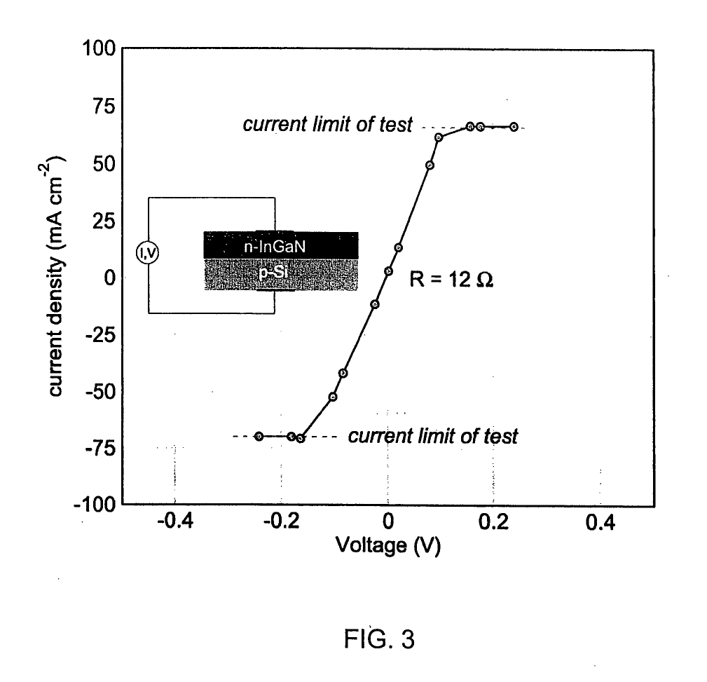

In accordance with an exemplary embodiment of the present invention, a layer of n-type nitride material is deposited on p-type Si (111) to form a junction. Electrical testing was performed on a tunnel junction between n-InGaN and p-Si (111). Particularly, the electrical resistance of the junction was measured for a layer of In_{0.4}Ga_{0.6}N composition on p-type Si (i.e., approximately the composition that has its conduction band aligned with the valence band of Si). The electrical resistance of this junction was determined to be both ohmic and low. The observed resistance was 12 ohms and behavior was ohmic up to the current limit of the test device. FIG. 3 shows a current-voltage curve for this junction between n-In_{0.4}Ga_{0.6},N and p-type Si. The measured composition of the InGaN alloy was close to that predicted to yield the near-perfect band alignment illustrated in FIG. 2. The current-voltage curve in FIG. 3 is fully symmetric, indicating the absence of electrical barriers at the hetero-interface (the junction). The junction has ohmic character and low resistance to a current density at least as large as 50 mA cm⁻², which is higher than the current in a typical solar cell. Thus the junction between InGaN and Si does not present a limit to the photocurrent that can be generated from a solar cell comprising an indium-nitride based junction in accordance with an exemplary embodiment of the present invention. In general, it is useful to have the ohmic tunnel junctions with resistances less than the series resistance of the component semiconductors. For optimized solar cells, the front and back ohmic contacts should be in the order of few ohms/cm².

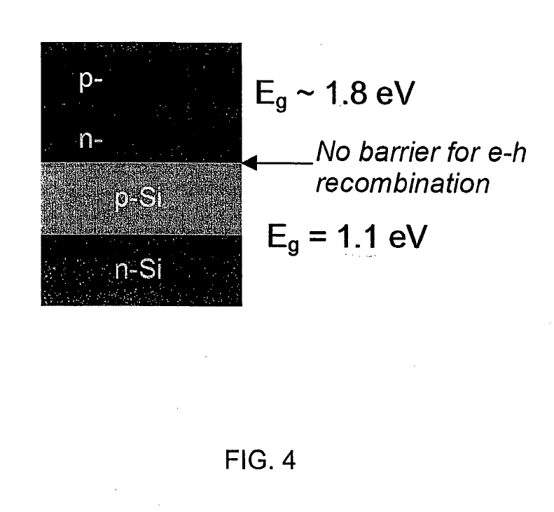

FIG. 4 illustrates a two-junction tandem cell with an indium-nitride based material with a band gap of 1.8 eV as the top cell and Si (band gap=1.1 eV) as the bottom cell in accordance with an exemplary embodiment of the present invention. It is appreciated that this configuration is close to the ideal for a top cell matched to Si in terms of maximum power conversion efficiency.

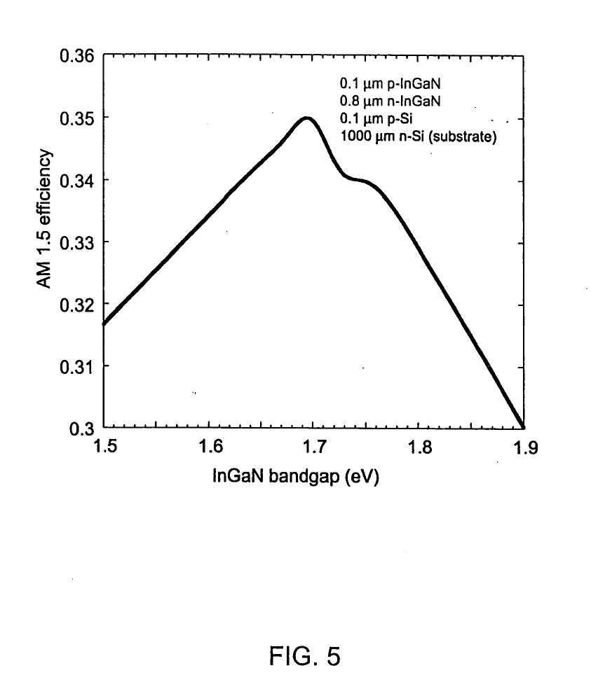

Using accepted values for light absorption and charge transport parameters for InGaN and Si, FIG. 5 shows calculated efficiency values for a InGaN/Si tandem cell as a function of the InGaN band gap in accordance with an exemplary embodiment of the present invention. The cell structure comprised 0.1 μm of p-InGaN, 0.8 μm of n-InGaN, 0.1 μm of p-Si and 1000 μm n-Si as substrate. The efficiencies are calculated for the AM (air mass) 1.5 direct solar spectrum (ASTM terrestrial reference spectrum for photovoltaic performance evaluation). Specifically, FIG. 5 shows calculated 300 K AM 1.5 efficiency of a two junction (2J) InGaN/Si tandem solar cell. Efficiencies of over 30% are predicted for a range of InGaN top cell band gaps. The maximum efficiency is 35% using InGaN with a band gap of just under 1.7 eV (In_{0.5}Ga_{0.5}N). The following InGaN electrical and transport parameters were used in the calculation: electron mobility, 300 cm² V⁻¹ s⁻¹; hole mobility, 50 cm² V⁻¹ s⁻¹; electron effective mass 0.07 m₀; hole effective mass 0.7 m₀; and zero surface recombination velocities. For the InGaN/Si tandem cell, the maximum value is well in excess of 30% and reaches 35% for an optimal configuration. A low-resistance tunnel junction between the cells allows the efficient recombination of carriers at the junction, thereby enabling the present invention to attain actual efficiency close to the theoretical limit. Further, the present invention greatly simplifies the design of a 2J cell by eliminating the need for heavily doped tunnel junctions. That is, the present invention advantageously eliminates the doping steps required in fabricating the currently available tandem solar cells to ensure recombination at the cell junction regions.

It is appreciated that there are other pairs of semiconductors which can be used to form a low resistance tunnel junction of the present invention. For example, the conduction band of InAs is well aligned with the valence band of GaSb. While the band gaps of these materials (both are less than 1 eV) are below what is considered ideal for a tandem cell responding to solar light, a InAs/GaSb design can be optimized for converting near-infrared and infrared light from heat sources in a thermo-photovoltaic cell that can produce electricity from heat.

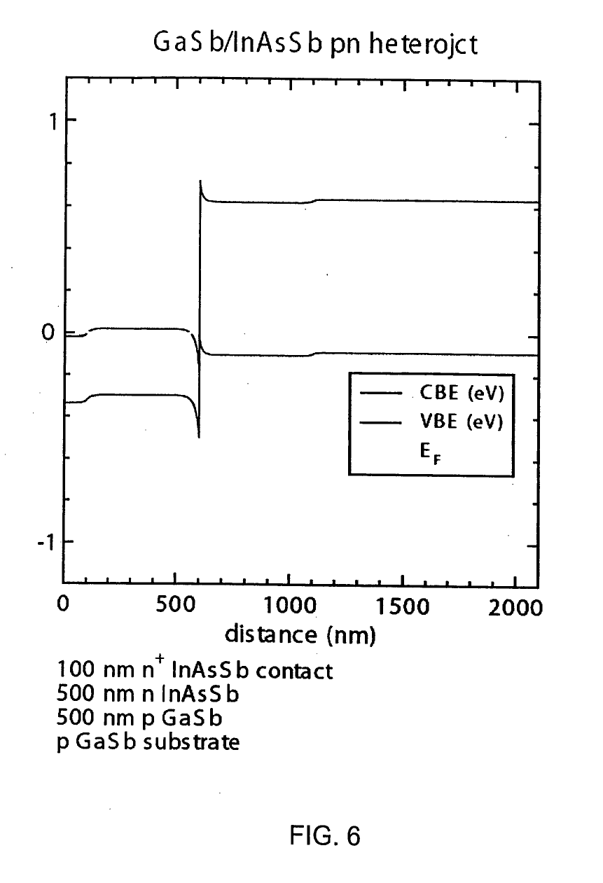

Incorporating small (up to few %) amounts of Sb into InAs to form InAsSb alloys and/or As or P into GaSb to form GaAsSb alloys, the InAsSb and GaAsSb alloys can be used to match lattice parameters and to modify the band offsets between constituent semiconductors forming the tunnel junction in accordance with an exemplary embodiment of the present invention. FIG. 6 shows calculated band diagram for a p-GaSb and n-InAs_{0.94}Sb_{0.06} junction. The low barrier at the interface indicates a very low resistance junction. Calculations were based on the following cell structure:

| Layer Composition | Doping Concentration | Layer Thickness |
|---|---|---|
| n-InAsSb (contact layer) | 1 × 10¹⁸ cm⁻³ | 100 nm |
| n-InAsSb | 1 × 10¹⁷ cm⁻³ | 500 nm |
| p-GaSb | 1 × 10¹⁷ cm⁻³ | 500 nm |
| p-GaSb (substrate) | 2 × 10¹⁷ cm⁻³ | 1000 nm |

This invention has been described herein in considerable detail to provide those skilled in the art with information relevant to apply the novel principles and to construct and use such specialized components as are required. However, it is to be understood that the invention can be carried out by different equipment, materials and devices, and that various modifications, both as to the equipment and operating procedures, can be accomplished without departing from the scope of the invention itself.

We claim:

1. A semiconductor structure, comprising:
a first photovoltaic cell comprising a first material; and
a second photovoltaic cell comprising a second material and connected in series to said first photovoltaic cell; and
wherein a conduction band edge of said first material adjacent said second material is at most 0.1 eV higher than a valence band edge of said second material adjacent the said material.

2. The semiconductor structure of claim 1, wherein said first material of said first photovoltaic cell comprises In₁₋ₓAlₓN or In_{1-y}Ga_{y}N and said second material of said second photovoltaic cell comprises silicon or germanium.

3. The semiconductor structure of claim 1, wherein said first material of said first photovoltaic cell comprises InAs and said second material of said second photovoltaic cell comprises GaSb.

4. The semiconductor structure of claim 1, wherein said first material of said first photovoltaic cell comprises InAsSb and said second material of said second photovoltaic cell comprises GaAsSb.

5. A semiconductor structure, comprising:
a p-type silicon layer; and
an n-type semi-conducting nitride layer in contact with said p-type silicon layer; and
wherein said n-type semi-conducting nitride layer has a conduction band edge at most 0.1 eV higher than a valence band edge of said p-type silicon layer.

6. The semiconductor structure of claim 5, wherein a current-voltage characteristic of said semiconductor structure is symmetric.

7. The structure of claim 5, wherein a junction formed by said p-type silicon layer and said n-type semi-conducting nitride layer has a resistance substantially equal to a series resistance of the silicon and the nitride.

8. The semiconductor structure of claim 5, wherein said n-type semi-conducting nitride is selected from a group consisting of In₁₋ₓAlₓN and In_{1-y}Ga_{y}N.

9. The semiconductor structure of claim 8, wherein x is between 0.2 and 0.6 and y is between 0.4 and 0.6.

10. The semiconductor structure of claim 5, wherein said p-type silicon layer is (111) silicon.

11. The semiconductor structure of claim 5, further comprising a p-type semi-conducting nitride layer in contact with said n-type semi-conducting nitride layer and an n-type silicon layer in contact with said p-type silicon layer.

12. The semiconductor structure of claim 5, wherein said n-type semi-conducting nitride layer is part of a first photovoltaic cell and said p-type silicon layer is part of a second photovoltaic cell, and wherein said first photovoltaic cell and said second photovoltaic cell are connected together in series.
